(19) United States
(12) Patent Application Publication
(10) Pub. No.: US 2021/0127487 A1
(43) Pub. Date: Apr. 29, 2021

(54) BASE MATERIAL FOR PRINTED CIRCUIT BOARD AND PRINTED CIRCUIT BOARD

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Kenichiro AIKAWA, Osaka (JP); Motohiko SUGIURA, Osaka (JP); Takashi KASUGA, Osaka (JP); Kazuhiro MIYATA, Osaka (JP); Kayo HASHIZUME, Osaka (JP); Masamichi YAMAMOTO, Osaka (JP)

(21) Appl. No.: 17/057,132

(22) PCT Filed: Apr. 24, 2019
(86) PCT No.: PCT/JP2019/017332

§ 371 Date: Nov. 20, 2020

(30) Foreign Application Priority Data
May 25, 2018 (JP) 2018-101002

(51) Int. Cl. H05K 1/03; B32B 5/16; B32B 15/20; C23C 18/20; C23C 18/38

(52) U.S. Cl. CPC H05K 1/03; B32B 5/16; B32B 15/20; B32B 2457/08; C23C 18/38; H05K 2201/0344; B32B 2264/1055; C23C 18/20

(57) ABSTRACT

The base material for printed circuit board according to one aspect of the present disclosure is a base material for printed circuit board comprising a base film having an insulating property, a sintering layer inducing a plurality of copper particles and formed on at least one surface of the base film and an electroless copper plating layer formed on a surface of the sintering layer, the surface being on an opposite side to the base film, and filled in the sintering layer, and wherein a lightness L* of a surface of the electroless copper plating layer, the surface being on an opposite side to the sintering layer, is 45.0 or more and 85.0 or less, a chromaticity a* thereof is 5.0 or more and 25.0 or less, and a chromaticity b* thereof is 5.0 or more and 25.0 or less.

### TECHNICAL FIELD

This disclosure relates to base material for printed circuit board and printed circuit board. This application claims priority based on Japanese Application No. 2018-101002, filed May 25, 2018, and the entire contents of the Japanese patent application are incorporated herein by reference.

### BACKGROUND ART

The printed circuit board base material is widely used to obtain a flexible printed circuit board by having a metal layer on the surface of an insulating base film and forming an conductive pattern by etching this metal layer.

In recent years, the miniaturization and performance improvement of electronic devices have required higher density of the printed circuit board. As the base material for printed circuit board that satisfies the requirement of such high density, the base material for printed circuit board with reduced thickness of the conductive layer is required.

In addition, the base material for printed circuit board needs to have a high peel strength between the base film and the metal layer to prevent the metal layer from peeling off from the base film when the flexible printed circuit board is subjected to bending stress.

In response to such requirements, a base material for printed circuit board, in which a first conductive layer is formed by coating a surface of an insulating base material (base film) with conductivity ink containing copper particles and a metal inert agent and by sintering the conductivity ink, an electroless plating layer is formed on the first conductive layer by electroless plating, and a second conductive layer is formed by electroplating over the electroless plating layer, is proposed (see JP-A publication No. 2012-114152).

The base material for printed circuit board as described in the aforementioned publication can be made smaller in thickness because a metal layer is directly formed on the surface of the insulating base material without using an adhesive. In addition, the base material for printed circuit board as described in the aforementioned publication contains a metal inert agent in the sintering layer, thereby preventing a decrease in the peel strength of the metal layer due to the diffusion of copper ions. The base material for printed circuit board described in the aforementioned publication can be manufactured without expensive equipment such as vacuum facilities, and therefore can be provided at a relatively low cost.

### CITATION LIST

### Patent Literature

PTL 1: Japanese Unexamined Patent Application Publication No. 2012-114152

### SUMMARY OF INVENTION

A base material for printed circuit board according to one aspect of the present disclosure includes a base film having an insulating property, a sintering layer inducing a plurality of copper particles and formed on at least one surface of the base film, an electroless copper plating layer formed on a surface of the sintering layer, the surface being on an opposite side to the base film, and filled in the sintering layer, and wherein a lightness L* of a surface of the electroless copper plating layer, the surface being on an opposite side to the sintering layer, is 45.0 or more and 85.0 or less, a chromaticity a* thereof is 5.0 or more and 25.0 or less, and a chromaticity b* thereof is 5.0 or more and 25.0 or less.

A printed circuit board according to another aspect of the present disclosure includes a base film having an insulating property, a sintering layer including a plurality of copper particles and formed on at least one surface of the base film, an electroless copper plating layer formed on a surface of the sintering layer, the surface being on an opposite side to the base film, and filled in the sintering layer and an electroplating layer formed on a surface of the electroless copper plating layer, the surface being on an opposite side to the sintering layer, and wherein the sintering layer, the electroless copper plating layer and the electroplating layer are patterned in a planar view, and a lightness L* of one surface of the electroless copper plating layer is 45.0 or more and 85.0 or less, a chromaticity a* thereof is 5.0 or more and 25.0 or less, and a chromaticity b* thereof is 5.0 or more and 25.0 or less.

### BRIEF DESCRIPTION OF THE DRAWING

FIG. 1 is a schematic cross-sectional view showing a base material for printed circuit board in one embodiment of the present disclosure.

FIG. 2 is a schematic cross-sectional view of a printed circuit board of one embodiment of the present disclosure.

### EMBODIMENTS FOR IMPLEMENTING THE INVENTION

### Problems to be Solved by Present Disclosure

The inventors have investigated the base material for printed circuit board as described in the above-mentioned publication and found that the peel strength of the metal layer may decrease when held under a high temperature and humidity environment. In other words, it has been confirmed that the base material for printed circuit board described in the aforementioned publication may have insufficient weather resistance.

The present disclosure has been made based on the above-mentioned circumstances, and its objective is to provide a base material for printed circuit board and a printed circuit board having excellent weather resistance.

### Effect of the Disclosure

The base material for printed circuit board according to one embodiment of the present disclosure and the printed circuit board according to another embodiment of the present disclosure has excellent weather resistance.

### DESCRIPTION OF EMBODIMENTS OF INVENTION

A base material for printed circuit board according to one aspect of the present disclosure includes a base film having an insulating property, a sintering layer inducing a plurality of copper particles and formed on at least one surface of the base film; and an electroless copper plating layer formed on a surface of the sintering layer, the surface being on an opposite side to the base film, and filled in the sintering layer, and wherein a lightness L* of a surface of the electroless copper plating layer, the surface being on an opposite side to the sintering layer, is 45.0 or more and 85.0 or less, a chromaticity a* thereof is 5.0 or more and 25.0 or less, and a chromaticity b* thereof is 5.0 or more and 25.0 or less.

The base material for printed circuit board has a lightness L* of a surface of the electroless copper plating layer, the surface being on an opposite side to the sintering layer, being 45.0 or more and 85.0 or less, a chromaticity a* thereof being 5.0 or more and 25.0 or less, and a chromaticity b* thereof being 5.0 or more and 25.0 or less, thereby improving the peel strength between the base film and the sintering layer and reducing a degradation of peel strength when continuously used in a high temperature and high humidity environment. In addition, the base material for printed circuit board may be manufactured without special equipment such as vacuum facilities, and thus is relatively inexpensive to manufacture in spite of its excellent weather resistance.

In the base material for printed circuit board, it is preferable that an average particle size of the copper particles is 1 nm or more and 500 nm or less. Thus, by having the average particle size of the copper particles within the aforementioned range, it is relatively easy to form a dense and less porous sintering layer, and the peel strength between the base film and the metal layer may be further improved.

In the base material for printed circuit board, it is preferred that an arithmetic mean height Sa of the surface of the base film on which the sintering layer is formed is 0.01 μm or more and 0.04 μm or less. Thus, by having the arithmetic mean height Sa of a surface of the base film on which the sintering layer is formed within the aforementioned range, the peel strength between the base film and the metal layer may be further improved.

The printed circuit board according to another aspect of the present disclosure comprises a base film having an insulating property, a sintering layer including a plurality of copper particles and formed on at least one surface of the base film, an electroless copper plating layer formed on a surface of the sintering layer, the surface being on an opposite side to the base film, and filled in the sintering layer, and an electroplating layer formed on a surface of the electroless copper plating layer, the surface being on an opposite side to the sintering layer, and wherein the sintering layer, the electroless copper plating layer and the electroplating layer are patterned in a planar view, and a lightness L* of one surface of the electroless copper plating layer is 45.0 or more and 85.0 or less, a chromaticity a* thereof is 5.0 or more and 25.0 or less, and a chromaticity b* thereof is 5.0 or more and 25.0 or less.

The printed circuit board has the surface color of the electroless copper plating layer within the aforementioned range, the printed circuit board is suitably filled with plated copper in the sintering layer, resulting in a high peel strength between the base film and the sintering layer and a small decrease in peel strength, especially when used for a long time under a high temperature environment. In addition, the printed circuit board may be manufactured without special equipment such as vacuum equipment, and thus is relatively inexpensive to manufacture despite its excellent weather resistance.

Here, “sintering” includes not only a complete sintering state in which the particles are solidly joined together, but also a state in which the particles are in the preliminary stages of reaching a complete sintering state and are in close contact with each other, such that they are solidly joined together. Lightness L*, chromaticity a*, and chromaticity b* are values measured in accordance with JIS-Z8781-4 (2013). The “average particle size” is the average of the circular equivalent diameter of the particles in a cross-sectional scanning electron microscope image. The “arithmetic mean height (Sa)” of the surface of the base film where the sintering layer is formed is measured in accordance with ISO-25178 after removing the electroless copper plating layer and the sintering layer by etching with an acidic solution.

### Details of Embodiments of the Disclosure

Each embodiment of the base material for printed circuit board in the present disclosure will be described in detail with reference to the drawings below.

<Base Material for Printed Circuit Board>

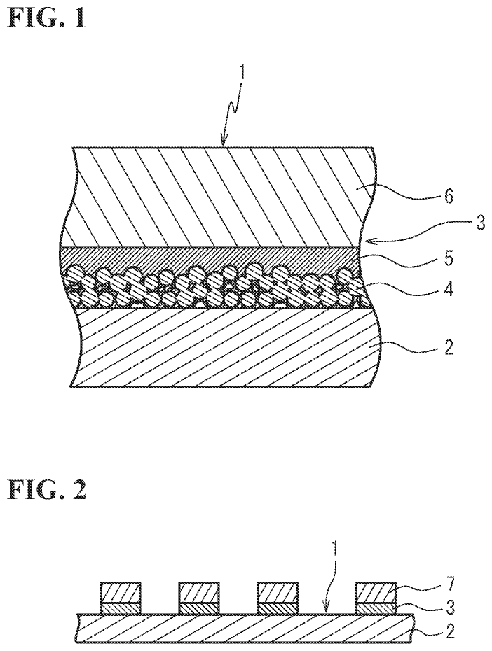

Base material for printed circuit board 1 shown in FIG. 1 has base film 2 having insulating property and metal layer 3 formed on one side of base film 2.

Metal layer 3 has sintering layer 4, which is formed by sintering a plurality of copper particles stacked on one side of base film 2, and electroless copper plating layer 5, which is formed on a surface of sintering layer 4, the surface being on an opposite side to base film 2. Metal layer 3 may further have an electroplating layer 6 on a surface of electroless copper plating layer 5, the surface being on an opposite side to sintering layer 4.

<Base Film>

As a material of base film 2, a flexible resin such as polyimide, liquid crystal polymer, fluoropolymer, polyethylene terephthalate, polyethylene naphthalate, or the like, a rigid material such as paper phenol, paper epoxy, glass composite, glass epoxy, polytetrafluoroethylene, glass base material, or the like, or a rigid flexible material compounded with a hard material and a soft material may be used. Among these, polyimide is particularly desirable because of its high binding power with copper oxide and the like.

The thickness of base film 2 is set based on a printed circuit board including the base material for printed circuit board and is not particularly limited. For example, as a lower limit of the average thickness of base film 2, 5 μm is preferable and 12 μm is more preferable. On the other hand, as an upper limit of the average thickness of base film 2, 2 mm is preferable and 1.6 mm is more preferable. If the average thickness of base film 2 is less than the lower limit, the strength of base film 2, and thus the strength of the base material for printed circuit board may become insufficient. On the contrary, if the average thickness of base film 2 exceeds the upper limit, the base material for printed circuit board may become unnecessarily thick.

It is preferable to apply hydrophilization treatment to the surface of base film 2 on which sintering layer 4 is formed. As the aforementioned hydrophilization treatment, for example, plasma treatment, in which the surface is hydrophilized by irradiating the surface with plasma, or alkali treatment, in which the surface is hydrophilized with an alkaline solution, may be employed. The hydrophilization treatment on base film 2 improves the adhesion to sintering layer 4 and the peel strength of metal layer 3. In addition, when sintering layer 4 is formed by coating and sintering the ink containing copper particles as described below, the surface tension of the ink on base film 2 is low and thus the ink may be easily applied evenly on base film 2.

A lower limit of the arithmetic mean height Sa of a surface of base film 2 on which sintering layer 4 is formed is preferably 0.01 μm. On the other hand, an upper limit of the arithmetic mean height Sa of the surface of base film 2 on which sintering layer 4 is formed is preferably 0.04 μm. If the arithmetic mean height Sa of the surface of base film 2 on which sintering layer 4 is formed is less than the lower limit, the adhesion force between base film 2 and sintering layer 4 may be insufficient. On the contrary, if the arithmetic mean height Sa of the surface of base film 2 on which sintering layer 4 is formed exceeds the upper limit, a void may be easily formed in a region near the interface of sintering layer 4 with base film 2, and sintering layer 4 may easily detach from base film 2 under a high temperature and high humidity environment. The arithmetic mean height Sa may be adjusted by applying a surface treatment such as plasma treatment, alkali treatment or wet blasting treatment, for example. The arithmetic mean height Sa may be adjusted so that the arithmetic mean height Sa is in the aforementioned range during the manufacture of base film 2.

<Sintering Layer>

Sintering layer 4 is formed by sintering a plurality of copper particles, which are stacked on one side of base film 2. Sintering layer 4 has a smaller porosity due to the filling of plated copper in gaps between the copper particles during the formation of electroless copper plating layer 5.

Sintering layer 4 may be formed, for example, by coating and sintering of an ink containing the copper particles. Thus, by using the ink containing copper particles, metal layer 3 may be easily and inexpensively formed on one side of base film 2.

As a lower limit of the area ratio of the sintered copper particles in the cross section of sintering layer 4 (not including the area of plated copper filled in the interstices of the copper particles during the formation of electroless copper plating layer 5), 50% is preferable and 60% is more preferable. On the other hand, as an upper limit of the area ratio of the sintered copper particles in the cross section of sintering layer 4, 90% is preferable and 80% is more preferable. If the area ratio of the sintered copper particles in the cross section of sintering layer 4 is less than the lower limit, the decrease in peel strength may not be sufficiently suppressed under a high temperature and high humidity environment. On the contrary, if the area ratio of the sintered copper particles in the cross section of sintering layer 4 exceeds the upper limit, base film 2 and the like may be damaged due to excessive heat during firing, and the base material for printed circuit board may become unnecessarily expensive due to difficulty in forming sintering layer 4.

As a lower limit of the average particle size of copper particles in sintering layer 4, 1 nm is preferable and 30 nm is more preferable. On the other hand, as an upper limit of the average particle size of the aforementioned copper particles, 500 nm is preferable and 100 nm is more preferable. If the average particle size of the copper particles is less than the lower limit, for example, the dispersion and stability of the copper particles in the ink may be reduced, which may make it difficult for the copper particles to be uniformly stacked on the surface of base film 2. On the contrary, if the average particle size of the copper particles exceeds the upper limit, the gap between the copper particles may become large and it may not be easy to reduce the porosity of sintering layer 4.

As a lower limit of the average thickness of sintering layer 4, 50 nm is preferable and 100 nm is more preferable. On the other hand, as an upper limit of the average thickness of sintering layer 4, 2 μm is preferable and 1.5 μm is more preferable. If the average thickness of sintering layer 4 is less than the lower limit, the conductivity may decrease due to a large number of areas where copper particles do not exist in a plan view. On the contrary, if the average thickness of sintering layer 4 exceeds the upper limit, it may be difficult to reduce the porosity of sintering layer 4 sufficiently or metal layer 3 may become unnecessarily thick.

In the vicinity of the interface of base film 2 and sintering layer 4, copper oxide based on copper of the copper particles or groups derived from copper oxide thereof (collectively referred to as “copper oxide, etc.”) or copper hydroxide based on copper of the copper particles or groups derived from copper hydroxide thereof (collectively referred to as “copper hydroxide, etc.”) are preferably present. In particular, it is desirable that both the copper oxide and the copper hydroxide are present. These copper oxide, etc. and copper hydroxide, etc. have relatively high adhesion both to base film 2 formed from resin and other materials and to sintering layer 4 formed from copper. Therefore, the presence of copper oxide, etc. or copper hydroxide, etc. in a region near the interface between base film 2 and sintering layer 4 improves the peel strength between base film 2 and sintering layer 4.

A lower limit of the amount of copper oxide, etc., per unit area in a region near the interface of between base film 2 and sintering layer 4 is preferably 0.1 μg/cm², and is more preferably 0.15 μg/cm². On the other hand, as an upper limit of the amount of copper oxide, etc. present per unit area, 10 μg/cm² is preferable, 5 μg/cm² is more preferable, and 1 μg/cm² is even more preferable. If the amount of copper oxide, etc. per unit area is less than the lower limit, the peel strength improvement effect of the copper oxide between base film 2 and sintering layer 4 may be reduced. On the contrary, if the amount of copper oxide, etc. per unit area exceeds the upper limit, it may be difficult to control the sintering of the copper particles.

A lower limit of the amount of copper hydroxide, etc. per unit in a region near the interface of base film 2 and sintering layer 4 is preferably 0.5 μg/cm², and is more preferably 1.0 μg/cm². On the other hand, as an upper limit of the amount of copper hydroxide, etc. present per unit area, 10 μg/cm² is preferable and 5 μg/cm² is more preferable. If the amount of copper hydroxide, etc. per unit area is less than the lower limit, it may be difficult to control the sintering of the copper particles to produce a large amount of copper oxide, etc. On the contrary, if the above-mentioned amount of copper hydroxide, etc. per unit area exceeds the upper limit, the copper oxide, etc. may not be able to improve the peel strength between sintering layer 4 and base film 2 due to a relative decrease in the copper oxide, etc.

As a lower limit of the existing amount ratio (mass ratio) of copper oxide, etc. to copper hydroxide, etc. in a region near the interface of base film 2 and sintering layer 4, 0.1 is preferable, and 0.2 is more preferable. On the other hand, as the upper limit of the existing amount ratio, 5 is preferable, 3 is more preferable, and 1 is even more preferable. If the existing amount ratio is less than the lower limit, the peel strength between base film 2 and sintering layer 4 may not be improved because the amount of copper hydroxide, etc. becomes too much in a region near the interface as compared to copper oxide, etc. On the contrary if the existing amount ratio exceeds the above-mentioned upper limit, it may be difficult to control the sintering of the copper particles.

<Electroless Copper Plating Layer>

Electroless copper plating layer 5 is formed by applying electroless copper plating to the outer surface of sintering layer 4. Electroless copper plating layer 5 is formed to impregnate sintering layer 4. In other words, the gaps between the copper particles forming sintering layer 4 are filled with electroless plated copper to reduce the voids inside sintering layer 4. In this way, by filling the gaps between copper particles with electroless plated copper, the voids between copper particles are reduced. Since such voids become a failure point, reducing the voids prevents sintering layer 4 from being delaminated from base film 2.

As a lower limit of the lightness L* of the outer surface of electroless copper plating layer 5 (opposite side to sintering layer 4), 45 is preferable, 50 is more preferable, and 60 is even more preferable. On the other hand, as an upper limit of the lightness L* of the outer surface of electroless copper plating layer 5, 85 is preferable, 80 is more preferable, and 70 is even more preferable. As a lower limit of the chromaticity a* of the outer surface of electroless copper plating layer 5, 5 is preferable, 8 is more preferable, and 10 is even more preferable. On the other hand, as an upper limit of the chromaticity a* of the outer surface of electroless copper plating layer 5, 25 is preferable, 20 is more preferable, and 18 is even more preferable. As a lower limit of the chromaticity b* of the outer surface of electroless copper plating layer 5, 5 is preferable, 8 is more preferable, and 10 is even more preferable. On the other hand, as an upper limit of the chromaticity b* of the outer surface of electroless copper plating layer 5, 25 is preferable, 20 is more preferable, and 18 is even more preferable. By keeping the color of the outer surface of electroless copper plating layer 5 within the aforementioned range, sintering layer 4 is made reasonably dense and the peel strength and weather resistance between base film 2 and sintering layer 4 may be improved.

As a lower limit of the average thickness of electroless copper plating layer 5 formed on the outer surface of sintering layer 4 (not including the thickness of the plated copper inside sintering layer 4), 0.2 μm is preferable and 0.3 μm is more preferable. On the other hand, as an upper limit of the average thickness of electroless copper plating layer 5 formed on the outer surface of sintering layer 4, 1 μm is preferable and 0.5 μm is more preferable. If the average thickness of electroless copper plating layer 5 formed on the outer surface of sintering layer 4 is less than the lower limit, the peel strength between base film 2 and metal layer 3 may be insufficient because electroless copper plating layer 5 is not sufficiently filled into the gaps between the copper particles of sintering layer 4 and the porosity cannot be sufficiently reduced. On the contrary, if the average thickness of electroless copper plating layer 5 formed on the outer surface of sintering layer 4 exceeds the upper limit, the time required for electroless copper plating may be long and the manufacturing cost may increase unnecessarily.

<Electroplating Layer>

Electroplating layer 6 is electroplated on the outer side of sintering layer 4, i. e., the outer surface of electroless copper plating layer 5. This electroplating layer 6 allows the thickness of metal layer 3 to be adjusted easily and accurately. Also, by using electroplating, the thickness of metal layer 3 may be increased in a short time.

Copper, nickel, silver and other metals with good conductivity may be used for this electroplating. Of these, copper or nickel is particularly preferred because of its low cost and excellent conductivity.

The thickness of electroplating layer 6 is set according to the type and thickness of the conductive pattern required for the printed circuit board formed using base material for printed circuit board 1, and is not particularly limited. In general, as a lower limit of the average thickness of electroplating layer 6, 1 μm is preferable and 2 μm is more preferable. On the other hand, as an upper limit of the average thickness of electroplating layer 6, 100 μm is preferable and 50 μm is more preferable. If the average thickness of electroplating layer 6 is less than the lower limit, metal layer 3 may be easily damaged. On the contrary, if the average thickness of electroplating layer 6 exceeds the upper limit, base material for printed circuit board 1 may become unnecessarily thick or the flexibility of base material for printed circuit board 1 may be insufficient.

<Method of Producing a Base Material for Printed Circuit Board>

The method of manufacturing the base material for printed circuit board comprises: forming copper particles; preparing ink using the copper particles obtained in the copper particle formation process; coating one side of base film 2 having an insulating property with the ink obtained in the ink preparation process; sintering the ink coating film formed in the coating process; electroless copper plating the outer surface of sintering layer 4 formed in the sintering process so that the lightness L* of the surface is 45.0 or more and 85.0 or less, chromaticity a* thereof is 5.0 or more and 25.0 or less, and chromaticity b* thereof is 5.0 or more and 25.0 or less; and electroplating the outer side of sintering layer 4 (outer surface of the electroless copper plating layer).

<Copper Particle Formation Process>

The method for forming copper particles in the above-described copper particle formation process includes a high temperature treatment method, a liquid-phase reduction method, a gas phase method, or the like. Among those, the liquid-phase reduction method in which copper particles are deposited by reducing copper ions with a reducing agent in an aqueous solution is preferable.

For example, the liquid-phase reduction method is provided with a reduction step in which a copper ion is reduced by a reducing agent for a certain period of time in a solution in which a water-soluble copper compound and a dispersant are dissolved in water, the copper compound being a source of a copper ion that forms copper particles.

Water-soluble copper compounds that are a source of copper ions may be copper (II) nitrate (Cu(NO₃)₂) and copper (II) sulfate pentahydrate (CuSO₄/5H₂O), for example.

When copper particles are formed by the liquid-phase reduction method, various reducing agents capable of reducing and precipitating copper ions in a liquid phase (aqueous solution) reaction system may be used as reducing agents. This reducing agent may include, for example, sodium borohydride, sodium hypophosphite, hydrazine, transition metal ions such as trivalent titanium ions and divalent cobalt ions, reducing sugars such as ascorbic acid, glucose and fructose, polyhydric alcohols such as ethylene glycol and glycerin, and the like.

The titanium redox method is a method in which copper ions are reduced by the redox action of trivalent titanium ions when they are oxidized to tetravalent, and copper particles are deposited. Copper particles obtained by the titanium redox method have a small and uniform particle size and are almost spherical in shape. This forms a dense layer of copper particles and may easily reduce the voids in sintering layer 4.

To adjust the size of the copper particles, the type and proportion of copper compounds, dispersants, and reducing agents are adjusted. Furthermore, in the reduction step of the reduction reaction of the copper compound, the agitation speed, temperature, time, pH, etc. may be adjusted.

In particular, as a lower limit of the temperature in the reduction step, 0° C. is preferable and 15° C. is more preferable. On the other hand, as an upper limit of the temperature in the reduction step, 100° C. is preferable, 60° C. is more preferable, and 50° C. is even more preferable. If the temperature in the reduction step is less than the lower limit, the reduction efficiency may be insufficient. On the contrary, if the temperature in the reduction step exceeds the upper limit described above, the growth rate of the copper particles may be too fast and the adjustment of the particle size may not be easy.

The pH of the reaction system in the reduction step should be 7 or more and 13 or less to obtain copper particles with a small particle size, as in the present embodiment. The pH of the reaction system may be adjusted to the aforementioned range by using a pH adjuster. General acid or alkali such as hydrochloric acid, sulfuric acid, sodium hydroxide, sodium carbonate or the like is used as the pH adjuster, but nitric acid and ammonia, which do not contain impurity elements, are preferred, especially to prevent degradation of the peripheral components. The aforementioned impurities are, for example, alkali metals and alkaline earth metals, halogen elements such as chlorine, sulfur, phosphorus, boron, etc.

<Ink Preparation Process>

In the ink preparation process, the ink containing copper particles forming sintering layer 4 is prepared.

As an ink containing the copper particles, an ink containing a dispersion medium of copper particles and a dispersant for uniformly dispersing the copper particles in this dispersion medium is suitably used. By using the ink in which the copper particles are uniformly dispersed in this manner, the copper particles may be uniformly adhered to the surface of base film 2 and a uniform sintering layer 4 may be formed on the surface of base film 2.

The dispersant included in the aforementioned ink is not particularly limited, but it is preferable to use a polymeric dispersant having a molecular weight of 2,000 to 300,000, inclusive. Thus, by using a polymeric dispersant with a molecular weight in the aforementioned range, the copper particles may be well dispersed in the dispersion medium and the film quality of the resulting sintering layer 4 may be made dense and defect-free. If the molecular weight of the dispersant is less than the aforementioned lower limit, the effect of preventing the agglomeration of copper particles and maintaining dispersion may not be sufficient, resulting in the possibility that the sintering layer formed on base film 2 may not be dense and free of defects. On the contrary, if the molecular weight of the dispersant exceeds the aforementioned upper limit, a proportion of the dispersant is too large and may inhibit the sintering of copper particles between each other in the sintering process conducted after the coating of the ink, as a result voids occurs. If a proportion of the dispersant is too large, the denseness of the film quality of sintering layer 4 may be reduced and the decomposition residues of the dispersant may reduce the conductivity.

The aforementioned dispersant is preferably free of sulfur, phosphorus, boron, halogen and alkali from the viewpoint of preventing degradation of parts. Preferred dispersant is that whose molecular weight is in the aforementioned range and include amine-based polymeric dispersant such as polyethyleneimine and polyvinylpyrrolidone, hydrocarbon-based polymeric dispersant having a carboxylic acid group in the molecule such as polyacrylic acid and carboxymethyl cellulose, polymer dispersant with polar group such as copolymer each having a polyethyleneimine moiety and a polyethylene oxide moiety in one molecule thereof, Poval (polyvinyl alcohol), styrene-maleic acid copolymer and olefin-maleic acid copolymer.

The dispersant may also be added to the reaction system in the form of a solution dissolved in water or a water-soluble organic solvent. As a proportion of dispersant content, it is preferable to have 1 part by mass or more and 60 parts by mass or less per 100 parts by mass of copper particles. The dispersant surrounds the copper particles to prevent agglomeration and disperse the copper particles well. However, if the content of the dispersant is less than the aforementioned lower limit, this anti-agglomeration effect may be insufficient. On the contrary, if the content of the dispersant exceeds the above-mentioned upper limit, the excess dispersant may inhibit the sintering of the copper particles in the sintering process after the coating of the ink, resulting in the formation of voids, and the decomposition residues of the polymeric dispersant may remain as impurities in the sintering layer and reduce the conductivity.

As for a ratio of water as the dispersion medium in the ink, a water content of 20 parts by mass or more and 1900 parts by mass or less per 100 parts by mass of copper particles is preferred. The water in the dispersion medium swells the dispersant sufficiently to disperse the copper particles surrounded by the dispersant, but if the ratio of water in the dispersion medium is less than the aforementioned lower limit, the swelling effect of the water on the dispersant may be insufficient. On the contrary, if the ratio of water content exceeds the aforementioned upper limit, the ratio of copper particles in the ink may be reduced and a good sintering layer having the required thickness and density may not be formed on the surface of base film 2.

Various organic solvents that are water-soluble may be used as organic solvents that are blended with the ink as needed. As specific examples, alcohol such as methyl alcohol, ethyl alcohol, n-propyl alcohol, isopropyl alcohol, n-butyl alcohol, isobutyl alcohol, sec-butyl alcohol and tert-butyl alcohol, ketones such as acetone, methyl ethyl ketone, etc., polyhydric alcohols such as ethylene glycol and glycerin, and other esters, and glycol ethers such as ethylene glycol monoethyl ether and diethylene glycol monobutyl ether, etc. may be listed.

As a ratio of water-soluble organic solvent content, it is preferable to have 30 parts by mass or more and 900 parts by mass or less per 100 parts by mass of copper particles. If the ratio of the water-soluble organic solvent is less than the aforementioned lower limit, the effect of adjusting the viscosity and vapor pressure of the dispersion by the organic solvent may not be sufficient. On the contrary, if the ratio of the water-soluble organic solvent content exceeds the aforementioned upper limit, the swelling effect of the dispersant by the water will be insufficient, and aggregation of the copper particles may occur in the ink.

When copper particles are produced by the liquid-phase reduction method, the copper particles precipitated in the liquid phase (aqueous solution) reaction system may be prepared by filtering, washing, drying, crushing, or the like, and once the copper particles are powdered, the ink may be prepared by using them. In this case, powdered copper particles, water which is a dispersion medium, a dispersant and, if necessary, a water-soluble organic solvent may be blended in a predetermined ratio to make an ink containing copper particles. However, it is preferable to prepare the ink using, as a starting material, a liquid phase (aqueous solution) in which the copper particles are deposited. Specifically, the liquid phase (aqueous solution) containing the precipitated copper particles is subjected to ultrafiltration, centrifugation, water rinsing, electrodialysis, etc. to remove the impurities, and then concentrated to remove the water if necessary. On the contrary, after adjusting the concentration of the copper particles by adding water, the ink containing the copper particles is prepared by further blending a water-soluble organic solvent in a predetermined proportion if necessary. This method may prevent the formation of coarse and irregularly shaped particles due to agglomeration of copper particles during drying, and it is easy to form a dense and uniform sintering layer 4.

<Coating Process>

In the coating process, the ink is coated on one side of base film 2. Conventionally known coating methods such as, for example, spin-coating, spray-coating, bar-coating, die-coating, slit-coating, roll-coating, dip-coating, or the like may be used to coat the ink. For example, the ink may be coated on only part of one side of base film 2 by screen printing, dispensing, or the like.

<Sintering Process>

In the aforementioned sintering process, the coating of the ink coated on one side of base film 2 is preferably sintered by heat treatment after drying. The solvent and dispersant of the ink evaporates or thermally decomposes, and the remaining copper particles are sintered and adhered to one side of base film 2 to obtain sintering layer 4.

In particular, the color of the surface of electroless copper plating layer 5 may be adjusted by heat treatment after adjusting the amount of water and other residues on the surface of the aforementioned coating by performing a drying process.

In a region near the interface of sintering layer 4 with base film 2, the copper particles are oxidized during sintering. As result, the formation of copper hydroxide derived from copper of the copper particles or the formation of groups derived from the copper hydroxide is suppressed, while copper oxide derived from copper of the copper particles or groups derived from the copper oxide is produced. Specifically, for example, when copper is used as a copper particle, copper oxide and copper hydroxide are formed in a region near the interface of sintering layer 4 with base film 2. The copper oxide formed in a region near the interface of sintering layer 4 binds strongly to the polyimides contained in base film 2, thus increasing the peel strength between base film 2 and sintering layer 4.

The aforementioned sintering is preferably performed under an atmosphere containing a certain amount of oxygen. As a lower limit of the oxygen concentration of the atmosphere during sintering, 1 volume ppm is preferable, and 10 volume ppm is more preferable. On the other hand, as an upper limit of the oxygen concentration, 10,000 volume ppm is preferable and 1,000 volume ppm is more desirable. If the oxygen concentration is less than the lower limit, the amount of copper oxide formation in a region near the interface of sintering layer 4 may be reduced and the adhesion strength between base film 2 and sintering layer 4 may not be sufficiently improved. On the contrary, if the oxygen concentration exceeds the upper limit, the copper particles may be excessively oxidized and the conductivity of sintering layer 4 may be reduced.

As a lower limit of the aforementioned sintering temperature, 150° C. is preferable and 200° C. is more preferable. On the other hand, as an upper limit of the aforementioned sintering temperature, 500° C. is preferable and 400° C. is more preferable. If the sintering temperature is less than the lower limit, the amount of copper oxide formation in a region near the interface of sintering layer 4 may be reduced and the adhesion between base film 2 and sintering layer 4 may not be sufficiently improved. On the contrary, if the sintering temperature exceeds the upper limit described above, base film 2 may be deformed when base film 2 is an organic resin such as polyimide.

<Electroless Copper Plating Process>

In the aforementioned electroless copper plating process, electroless copper plating layer 5 is formed on a surface of sintering layer 4, the surface being on an opposite side to base film 2 by applying electroless copper plating to sintering layer 4 formed on one side of base film 2 in the sintering process described above.

The aforementioned electroless copper plating is preferably performed together with, for example, a cleaner step, a water-washing step, an acid treatment process, a water-washing step, a pre-dip step, an activator step, a water-washing step, a reduction step, a water-washing step, a drying process or the like.

It is desirable to further perform a heat treatment of the material after forming electroless copper plating layer 5 by electroless copper plating. Heat treatment after the formation of electroless copper plating layer 5 further increases the copper oxide, etc. in a region near the interface of sintering layer 4 with base film 2, resulting in further increasing the adhesion between base film 2 and sintering layer 4. The temperature and oxygen concentration of the heat treatment after the electroless copper plating may be the same as the sintering temperature and oxygen concentration in the sintering process described above.

<Electroplating Process>

In the electroplating process, an electroplating layer 6 is formed on the outer surface of electroless copper plating layer 5 by electroplating. In this electroplating process, the overall thickness of metal layer 3 is increased to the desired thickness.

This electroplating may be performed using a conventionally known electroplating bath suitable for the metal to be plated, such as copper, nickel or silver, for example, and selecting appropriate conditions so that metal layer 3 of the desired thickness is formed rapidly and without defects.

<Advantages>

Base material for printed circuit board 1 has an excellent weather resistance as the color of a surface of the electroless copper plating layer, the surface being on the opposite side to the sintering layer, is set within the range of the above-described, which results in a small decrease in peel strength between base film 2 and sintering layer 4, and thus between base film 2 and metal layer 3, even in a high temperature and high humidity environment.

The aforementioned base material for printed circuit board 1 may be manufactured without special equipment such as vacuum facilities, and thus may be manufactured relatively inexpensively despite the large peel strength of the base film 2 and metal layer 3.

[Printed Circuit Board]

The printed circuit board is formed using base material for printed circuit board 1 as shown in FIG. 1, using a subtractive method or a semi-additive method. More particularly, the printed circuit board is manufactured by forming a conductive pattern by a subtractive method or a semi-additive method utilizing metal layer 3 of base material for printed circuit board 1.

In the subtractive method, a photosensitive resist is coated on the surface of metal layer 3 of base material for printed circuit board 1 shown in FIG. 1, and the resist is patterning corresponding to the conductive pattern by exposure and development. Next, metal layer 3 is removed by etching, using the patterned resist as a mask, except for the conductive pattern. And finally, by removing the remaining resist, the printed circuit board having an conductive pattern formed from the remaining portion of metal layer 3 of base material for printed circuit board 1 is obtained.

In the semi-additive method, a photosensitive resist is coated on the surface of metal layer 3 of base material for printed circuit board 1 as shown in FIG. 1, and an opening corresponding to the conductive pattern is patterned on the resist by exposure and development. Then, conductive layer is selectively formed on metal layer 3 exposed in the opening of the mask as a seed layer by plating using the patterned resist as a mask. Thereafter, by removing the resist and then removing the surface of the conductive layer and metal layer 3 wherein the conductive layer is not formed by etching, the printed circuit board having the conductive pattern formed by stacking additional conductive layer 7 on the remaining portion of metal layer 3 of base material for printed circuit board 1 as shown in FIG. 2 is obtained.

<Advantages>

Since the printed circuit board is manufactured using base material for printed circuit board 1, the decrease in adhesion between base film 2 and sintering layer 4 is small even in a high temperature and high humidity environment, and the conductive pattern is difficult to peel off because of its excellent weather resistance.

The printed circuit board may be inexpensively manufactured because it is formed by a general subtractive method or semi-additive method using inexpensive base material for printed circuit board 1.

### Other Embodiments

The embodiments disclosed here should be considered illustrative in all respects and not restrictive. The scope of the invention is not limited to the configurations of the foregoing embodiments, but is intended to be indicated by the claims and to include all changes within the meaning and scope of the claims and equal to the claims.

The base material for printed circuit board may have a metal layer formed on both sides of the base film.

The base material for printed circuit board may not have an electroplating layer, especially when used to produce the printed circuit board by the semi-additive method.

The sintering layer of the base material for printed circuit board may be formed by laminating and sintering copper particles on the surface of the base film by other means without using ink.

### Example

The invention will now be described in detail based on the examples, but the invention is not to be construed in a limiting manner based on the description of the examples.

<Prototype of Base Material for Printed Circuit Board>

In order to verify the effectiveness of the present disclosure, four types of base materials for printed circuit boards were manufactured in prototypes No. 1 to 4 with different manufacturing conditions. The color of the surface of the electroless copper plating layer and the peel strength of the metal layer before and after the weathering test were measured for each of the prototypes No. 1 to No. 4 of the printed circuit board base material.

(Prototype No. 1)

First of all, copper particles with an average particle size of 75 nm were used as copper particles, and the ink with a copper concentration of 26 mass % was made by dispersing these particles in water. Next, a polyimide film (Kaneka's Apical NPI) with an average thickness of 12 μm was used as an insulating base film, and the ink was coated on one side of this polyimide film, dried in air, and then the moisture on the surface was further removed by blowing compressed air to form a dry coating with an average thickness of 0.15 μm. The surface roughness of the ink layer formed was 0.032 μm. The sintering layer was then formed by sintering the dry-coated polyimide film at 350° C. for 2 hours in a nitrogen atmosphere with an oxygen concentration of 10 volume ppm. Then, electroless plating of copper was performed on a surface of the sintering layer, the surface being on an opposite side to the base film, to form an electroless copper plating layer with an average thickness of 0.25 μm from the outer surface of the sintering layer. In addition, a prototype No. 1 of the printed circuit board base material was obtained by heat treatment at 350° C. for 2 hours in a nitrogen atmosphere with an oxygen concentration of 150 volume ppm. The surface colors of the electroless copper plating layer of Prototype No. 1 were 70.4-64.5 in lightness L*, 13.6-14.7 in chromaticity a*, and 13.1-14.9 in chromaticity b*. Prototype No. 1 had a peel strength of 7.1-9.4 N/cm before weathering test, whereas the peel strength after weathering test was 5.3-5.7 N/cm.

(Prototype No. 2)

First of all, copper particles with an average particle size of 75 nm were used as copper particles, and the ink with a copper concentration of 26 mass % was made by dispersing these particles in water. Next, a polyimide film (Kaneka's Apical NPI) with an average thickness of 12 μm was used as an insulating base film, and the ink was coated on one side of this polyimide film, dried in air, and then the moisture on the surface was further removed by blowing compressed air to form a dry coating with an average thickness of 0.18 μm. The surface roughness of the ink layer formed was 0.092 μm. The sintering layer was then formed by sintering the dry-coated polyimide film at 350° C. for 2 hours in a nitrogen atmosphere with an oxygen concentration of 10 volume ppm. Then, electroless plating of copper was performed on a surface of the sintering layer, the surface being on an opposite side to the base film, to form an electroless copper plating layer with an average thickness of 0.25 μm from the outer surface of the sintering layer. In addition, a prototype No. 1 of the printed circuit board base material was obtained by heat treatment at 350° C. for 2 hours in a nitrogen atmosphere with an oxygen concentration of 150 volume ppm. The color of the surface of the electroless copper plating layer of Prototype No. 2 had a lightness L* of 54-60.1, a chromaticity a* of 12.2-13.5 and a chromaticity b* of 9.9-11.8. Prototype No. 2 had a peel strength of 7.4-8.7 N/cm before the weathering test, while the peel strength after the weathering test was 5.0-5.5 N/cm.

(Prototype No. 3)

First of all, copper particles with an average particle size of 75 nm were used as copper particles, and the ink with a copper concentration of 26 mass % was made by dispersing these particles in water. Next, a polyimide film with an average thickness of 12 μm (Kaneka's Apical NPI) was used as an insulating base film, and the ink was coated on one side of this polyimide film and dried in air to form a dry coating with an average thickness of 0.15 μm. The surface roughness of the ink layer formed was 0.032 μm. The sintering layer was then formed by sintering the dry-coated polyimide film at 350° C. for 2 hours in a nitrogen atmosphere with an oxygen concentration of 10 volume ppm. Then, electroless plating of copper was performed on a surface of the sintering layer, the surface being on an opposite side to the base film, to form an electroless copper plating layer with an average thickness of 0.25 μm from the outer surface of the sintering layer. In addition, a prototype No. 3 of the base material for printed circuit board was obtained by heat treatment at 350° C. for 2 hours in a nitrogen atmosphere with an oxygen concentration of 150 volume ppm. The color of the surface of the electroless copper plating layer of Prototype No. 1 has a lightness L* of 37.6-38.4, a chromaticity a* of 9.9-11.6, and a chromaticity b* of 5.9-10.3. Prototype No. 3 had a peel strength of 7.4-8.7 N/cm before the weathering test, while it had a peel strength of 3.8-4.8 N/cm after the weathering test.

(Prototype No. 4)

First of all, copper particles with an average particle size of 75 nm were used as copper particles, and the ink with a copper concentration of 26 mass % was made by dispersing these particles in water. Next, a polyimide film with an average thickness of 12 μm (Kaneka's Apical NPI) was used as an insulating base film, and the ink was coated on one side of this polyimide film and dried in air to form a dry coating with an average thickness of 0.18 μm. The surface roughness of the ink layer formed was 0.092 μm. The sintering layer was then formed by sintering the dry-coated polyimide film at 350° C. for 2 hours in a nitrogen atmosphere with an oxygen concentration of 10 volume ppm. Then, electroless plating of copper was performed on a surface of the sintering layer, the surface being on an opposite side to the base film, to form an electroless copper plating layer with an average thickness of 0.25 μm from the outer surface of the sintering layer. In addition, a prototype No. 4 of the base material for printed circuit board was obtained by heat treatment at 350° C. for 2 hours in a nitrogen atmosphere with an oxygen concentration of 150 volume ppm. The color of the surface of the electroless copper plating layer of Prototype No. 1 has a lightness L* of 33.8 to 35.4, a chromaticity a* of 5.1 to 8.5, and a chromaticity b* of −3.9 to −5.1. Prototype No. 4 had a peel strength of 7.4-8.7 N/cm before the weathering test, while the peel strength after the weathering test was 3.0-4.6 N/cm.

(Color of Electroless Copper Plating Layer)

The colors of the prototypes No. 1 to No. 4 of the base material for printed circuit boards were measured at multiple locations as color coordinates in accordance with JIS-Z8781-4 (2013). A Konica Minolta COLOR CR20 was used to measure color.

<Weathering Test>

In the weathering test, Sunshine carbon arc lamp (255 W/m²) was irradiated for 1,000 hours at 63±3° C. and 50±5% humidity in accordance with JIS-D0205 (1987) to the prototypes No. 1 to No. 4 of the base materials for printed circuit board.

<Peel Strength>.

The measurements of peel strength of the prototypes No. 1 to No. 4 of the base materials for printed circuit board before and after the weathering test were carried out in accordance with JIS-C6471 (1995), where multiple specimens were cut out and the metal layer was peeled off from the base film in a 180° direction.

Table 1 summarizes the peel strength and color of the electroless copper plating layer of the prototypes No. 1 to No. 4 of the base materials for printed circuit board before and after weathering tests.

| Prototype | | | No. 1 | No. 2 | No. 3 | No. 4 |
|---|---|---|---|---|---|---|
| Lightness L* | | minimum | 70.4 | 54.0 | 37.6 | 33.8 |
| | | value | | | | |
| | | maximum | 64.5 | 60.1 | 38.4 | 35.4 |
| | | value | | | | |
| Chromaticity a* | | minimum | 13.6 | 12.2 | 9.9 | 5.1 |
| | | value | | | | |
| | | maximum | 14.7 | 13.5 | 11.6 | 8.5 |
| | | value | | | | |
| Chromaticity b* | | minimum | 13.1 | 9.9 | 5.9 | −3.9 |
| | | value | | | | |
| | | maximum | 14.9 | 11.8 | 10.3 | −5.1 |
| | | value | | | | |
| Peel | Before | minimum | 7.1 | 7.4 | 7.4 | 7.4 |
| strength | weathering | value | | | | |
| [N/cm] | test | maximum | 9.4 | 8.7 | 8.7 | 8.7 |
| | | value | | | | |
| | After | minimum | 5.3 | 5.0 | 3.8 | 3.0 |
| | weathering | value | | | | |
| | test | maximum | 5.7 | 5.5 | 4.8 | 4.6 |
| | | value | | | | |

Thus, prototypes No. 1 and No. 2 with a lightness L* of 45.0 or more and 85.0 or less, a chromaticity a* of 5.0 or more and 25.0 or less, and a chromaticity b* of 5.0 or more and 25.0 or less on a surface of the electroless copper plating layer, the surface being on an opposite side to the sintering layer, had a relatively small decrease in peel strength by weathering tests. In contrast, the peel strength of Prototype No. 3 in which the lightness L* was less than 45.0 and Prototype No. 4 in which the chromaticity b* was less than 5.0 on a surface of the electroless copper plating layer, the surface being on an opposite side to the sintering layer, showed a relatively large decrease in peel strength by weathering tests.

### REFERENCE NUMERALS

1 base material for printed circuit board
2 base film
3 metal layer
4 sintering layer
5 electroless copper plating layer
6 electroplating layer
7 conductive layer

1. A base material for printed circuit board comprising:
a base film having an insulating property;
a sintering layer inducing a plurality of copper particles and formed on at least one surface of the base film; and
an electroless copper plating layer formed on a surface of the sintering layer, the surface being on an opposite side to the base film, and filled in the sintering layer, and wherein a lightness L* of a surface of the electroless copper plating layer, the surface being on an opposite side to the sintering layer, is 45.0 or more and 85.0 or less, a chromaticity a* thereof is 5.0 or more and 25.0 or less, and a chromaticity b* thereof is 5.0 or more and 25.0 or less.

2. The base material for printed circuit board according to claim 1,
wherein an average particle size of the copper particles is 1 nm or more and 500 nm or less.

3. The base material for printed circuit board according to claim 1,
wherein an arithmetic average height Sa of a surface of the base film on which the sintering layer is formed is 0.01 μm or more and 0.04 μm or less.

4. A printed circuit board comprising:
a base film having an insulating property;
a sintering layer including a plurality of copper particles and formed on at least one surface of the base film;
an electroless copper plating layer formed on a surface of the sintering layer, the surface being on an opposite side to the base film, and filled in the sintering layer; and
an electroplating layer formed on a surface of the electroless copper plating layer, the surface being on an opposite side to the sintering layer, and
wherein the sintering layer, the electroless copper plating layer and the electroplating layer are patterned in a planar view, and
a lightness L* of one surface of the electroless copper plating layer is 45.0 or more and 85.0 or less, a chromaticity a* thereof is 5.0 or more and 25.0 or less, and a chromaticity b* thereof is 5.0 or more and 25.0 or less.
